(19) United States
(12) Patent Application Publication
(10) Pub. No.: US 2015/0051853 A1
(43) Pub. Date: Feb. 19, 2015

(54) APPARATUS FOR PARAMETER ESTIMATION

(71) Applicants: CALSONIC KANSEI CORPORATION, Saitama (JP); KEIO UNIVERSITY, Tokyo (JP)

(72) Inventors: Atsushi Baba, Saitama (JP); Shuichi Adachi, Kanagawa (JP); Takahiro Kawaguchi, Kanagawa (JP)

(73) Assignees: KEIO UNIVERSITY, Tokyo (JP); CALSONIC KANSEI CORPORATION, Saitama (JP)

(21) Appl. No.: 14/353,793

(22) PCT Filed: Nov. 20, 2012
(86) PCT No.: PCT/JP2012/080522

§ 371 Date: Apr. 24, 2014

(30) Foreign Application Priority Data
Feb. 22, 2012 (JP) 2012-036089

(51) Int. Cl. G01R 31/36

(52) U.S. Cl. CPC G01R 31/3651; G01R 31/3634
USPC 702/63

(57) ABSTRACT

Provided is an apparatus for parameter estimation that, when performing parameter identification of a mathematical model expressing a target system as a differential equation, can reduce the estimation error of the parameters insofar as possible. The apparatus for parameter estimation includes a mathematical model expressing a target system as a differential equation, an input signal detection unit that detects an input signal to the target system, an output signal detection unit that detects an output signal from the target system, and a parameter identification unit that performs system identification by taking the input signal and the output signal as input and using these signals to identify parameters used in a transfer function of the mathematical model. The parameter identification unit performs, simultaneously with the system identification, continuous-time system identification of initial values of the transfer function based on the input signal and the output signal.

### TECHNICAL FIELD

The present invention relates to an apparatus for battery parameter estimation that estimates parameters used to express an equivalent circuit model for a target system of a battery or the like.

### BACKGROUND ART

In an electric vehicle, for example, a secondary battery is installed, and by knowing the State of Charge (SOC) of this battery, the drivable distance and the like are inferred.

Since the SOC cannot be directly measured, however, a conventional method for SOC estimation estimates the SOC indirectly by measuring other physical quantities, such as charge/discharge current and the like.

A known example of such a conventional method for SOC estimation is a coulomb counting method, in which a value is determined by measuring and integrating the charge/discharge current of the battery, and the ratio of this value to the full charge capacity is calculated.

This coulomb counting method has a variety of problems: error upon measuring the charge/discharge current accumulates, and the initial value when integrating is difficult to determine. Furthermore, once the estimated value of the SOC no longer matches the true value, adjustment cannot be made.

A different method is to determine the battery's Open Circuit Voltage (OCV), which is a physical quantity closely related to the SOC, and to estimate the SOC from the OCV.

When the SOC needs to be estimated while a load is being placed on the battery, such as while the electric vehicle is being driven, the OCV cannot be directly estimated. Therefore, the open circuit voltage estimation method estimates the OCV by measuring the charge/discharge current and the terminal current and using a battery equivalent circuit model, such as a Foster-type RC ladder circuit having a resistor and a capacitor in a parallel circuit, to identify parameters of the equivalent circuit.

In this open circuit voltage estimation method, constant observation data are unnecessary, and little error is accumulated. Since the change in OCV is small as compared to the change in SOC, however, the coulomb counting method is superior when, for example, estimating the amount of change in SOC over a short period of time.

Therefore, a method for SOC estimation that combines the advantages of both of the above methods is now often being used, as in the apparatus for SOC estimation disclosed in Patent Literature 1.

In this case, in order to determine the parameters of the battery equivalent circuit in the open circuit voltage estimation method, system identification theory is applied. In this case, a discrete-time system is often assumed.

Therefore, when estimating the parameters of a continuous-time system, an indirect method has been used whereby a discrete-time transfer function for the target system is first estimated and is then converted to a transfer function in continuous time.

This indirect method has had problems such as the following: the structure of the target system is not saved, the conversion from the discrete to the continuous is not unique, and furthermore the method works poorly with a short sampling period, is inaccurate with a long sampling period, and cannot adapt to a wide frequency.

For battery parameter estimation, among the above problems, the sampling period is particularly problematic.

Namely, the battery response includes an extremely slow mode with a time constant of several hundred to several thousand seconds.

In discrete-time system identification theory, the sampling period is an important setting parameter, and it is recommended that the sampling period be determined so that 5 to 8 sampling points be included in the rise time during the step response of the identification target. In this case, during battery parameter estimation, an appropriate sampling period is several hundred seconds, resulting in the problem that the sampling period cannot be shortened to obtain more data. Conversely, if the sampling period is shortened, a problem occurs in that a mode with a long time constant cannot be handled.

As compared to this method for discrete-time system identification, identification of a continuous-time system is better the shorter the sampling period is. Therefore, if continuous-time system identification is used, maximum use can be made of the collected data, and it is possible to improve the estimation accuracy of the parameters.

A known example of a conventional method for parameter estimation using such continuous-time system identification is disclosed in Patent Literature 2.

This conventional method for parameter estimation using continuous-time system identification identifies parameters of an unknown continuous system that can be described by a differential equation, such as a mechanical system, an electric motor system, or the like. Therefore, the conventional method for parameter estimation applies a continuous-time input signal to a continuous-time system that can be expressed as a differential equation and detects the continuous-time output signal of the system. With this method, sample values of the input signal and output signal are processed with digital filters, and the resulting filter processed signal is used to identify parameters of the differential equation. In this case, the conventional method for parameter estimation inputs a signal composed of input signal and output signal sample values into each of a group of stable digital filters in state-space form that can have state variables matching sample values of state variables of stable analog filters in state-space form. From the state variables of each digital filter, this method generates an identification signal corresponding to the parameters of the system and uses this identification signal to identify the parameters of the target system.

### CITATION LIST

### Patent Literature

Patent Literature 1: JP2011-515651A
Patent Literature 2: JP3513633B2

### SUMMARY OF INVENTION

Both of the conventional methods for parameter estimation disclosed in Patent Literature 1 and Patent Literature 2 perform system identification by assuming, even in the transfer function equation, either that the initial value of each state quantity is zero, or that the value is known and is equivalent to a predetermined value determined in advance by experiment.

In the case of a battery, however, the above initial values differ depending on the history of use conditions over time, since for example the capacitor in the battery equivalent circuit model may not be fully discharged.

As a result, applying the above system identifications to battery parameter identification leads to the problem of error occurring in the parameter estimation, and of error also occurring in the SOC estimation and the like.

In order to increase the accuracy of identification, it is necessary either to bring the actual initial value of the internal state of the battery close to zero or to perform experiments after bringing the value close to a known value. Therefore, it is necessary to set aside sufficient wait time for the chemical reaction and charge transfer in the battery to settle down. Furthermore, it is necessary to begin identification after performing charge/discharge to bring the SOC to a certain value.

Accordingly, problems occur in that a great deal of time is required to establish experiment conditions, and moreover identification of the battery equivalent circuit model cannot be performed periodically while an electric vehicle is being driven.

Another method is to use a variety of conditions when performing an experiment to determine, by table lookup, the initial value (OCV) considered to be the closest, yet this method also yields poor prediction accuracy of the initial value.

The present invention has been conceived in light of the above problems, and it is an object thereof to provide an apparatus for parameter estimation that, when performing parameter identification for an equivalent circuit model of a target system, can reduce the parameter estimation error insofar as possible.

To achieve this object, a method for battery state of charge estimation according to the present invention as recited in claim 1 is used in an apparatus for parameter estimation that includes a mathematical model expressing a target system as a differential equation; an input signal detection unit configured to detect an input signal to the target system; an output signal detection unit configured to detect an output signal from the target system; and a parameter identification unit configured to perform system identification by taking the input signal and the output signal as input and using the input signal and the output signal to identify a parameter used in a transfer function of the mathematical model, such that the parameter identification unit performs, simultaneously with the system identification, continuous-time system identification of an initial value of the transfer function based on the input signal and the output signal.

The method for parameter estimation as recited in claim 2 is used in the apparatus for parameter estimation as recited in claim 1, such that the parameter identification unit applies an SRIVC method to the continuous-time system identification.

The method for parameter estimation as recited in claim 3 is used in the apparatus for parameter estimation as recited in claim 1 or 2, such that the target system is a secondary battery, the input signal is a charge/discharge current of the secondary battery, and the output signal is a terminal voltage of the secondary battery.

According to the apparatus for parameter estimation as recited in claim 1, when performing parameter identification of the equivalent circuit model of the target system, the estimation error of the parameters can be reduced insofar as possible.

According to the apparatus for parameter estimation as recited in claim 2, the initial value can be set easily and reliably by using the SRIVC method.

According to the apparatus for parameter estimation as recited in claim 3, the overpotential and open circuit voltage of a secondary battery can be estimated accurately. Accordingly, the state of charge of the battery can also be inferred to a high degree of accuracy.

### BRIEF DESCRIPTION OF DRAWINGS

The present invention will be further described below with reference to the accompanying drawings, wherein:

FIG. 1 is a functional block diagram of an apparatus for battery state of charge estimation that includes the apparatus for parameter estimation of Embodiment 1 according to the present invention;

FIG. 2 illustrates a battery equivalent circuit used when estimating the overpotential and open circuit voltage in the apparatus for parameter estimation of Embodiment 1;

FIG. 3 illustrates a battery equivalent circuit, having an (n−1) order overpotential portion, that is used when determining the initial value in the apparatus for parameter estimation of Embodiment 1;

FIG. 4 shows I/O data used in a simulation of the apparatus for parameter estimation of Embodiment 1;

FIG. 5 is a Bode plot showing a comparison, using the I/O signals in FIG. 4, of the true system, continuous-time system identification of Embodiment 1, and discrete-time system identification;

FIG. 6 shows a comparison of true output values, output values determined by the continuous-time system identification of Embodiment 1, and output values determined by discrete-time system identification;

FIG. 7 is a Bode plot showing a comparison, using the I/O signals in FIG. 4, of the true values of the system, the estimated values for the open circuit voltage estimated using the continuous-time system identification of Embodiment 1, and the estimated values for the open circuit voltage estimated using discrete-time system identification;

FIG. 8 shows a comparison of the true state of charge, the state of charge determined by the continuous-time system identification of Embodiment 1, and output values determined by discrete-time system identification; and

FIG. 9 is a comparison table of equivalent circuit parameter values estimated by continuous-time system identification and by discrete-time system identification.

### DESCRIPTION OF EMBODIMENTS

The following describes the present invention in detail based on the embodiments illustrated in the drawings.

### Embodiment 1

First, the overall structure of an apparatus for battery state of charge estimation provided with the apparatus for parameter estimation of Embodiment 1 is described.

In the present embodiment, this apparatus for battery state of charge estimation is installed in an electric vehicle.

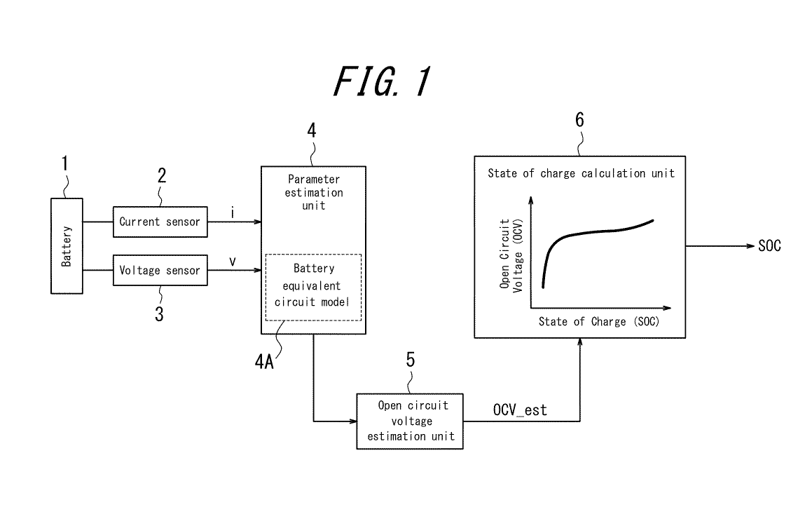

As illustrated in FIG. 1, the apparatus for battery state of charge estimation is connected to a battery 1 and includes a current sensor 2, a voltage sensor 3, a parameter estimation unit 4, an open circuit voltage estimation unit 5, and a state of charge calculation unit 6.

The battery 1 is a rechargeable battery, and a lithium-ion battery, for example, is used in the present embodiment. Note that in the present embodiment, the battery 1 is not limited to a lithium-ion battery and may be a different type of battery, such as a nickel-hydrogen battery or the like.

The current sensor 2 detects the magnitude of discharge current when power is being provided from the battery 1 to, for example, an electric motor that drives a vehicle. The current sensor 2 also detects the magnitude of charge current when an electric motor is caused to function as an electrical generator during braking to collect a portion of the braking energy or during charging by a ground-based power supply system. A detected charge/discharge current signal i is output to the parameter estimation unit 4 as an input signal.

The voltage sensor 3 detects the voltage value between terminals of the battery 1. A detected terminal voltage signal v is output to the parameter estimation unit 4.

Note that the current sensor 2 and voltage sensor 3 may adopt any of a variety of structures and forms and respectively correspond to the input signal detection unit and the output signal detection unit of the present invention.

The parameter estimation unit 4 is configured using a microcomputer and is provided with a battery equivalent circuit model 4A. The parameter estimation unit 4 corresponds to the parameter identification unit of the present invention.

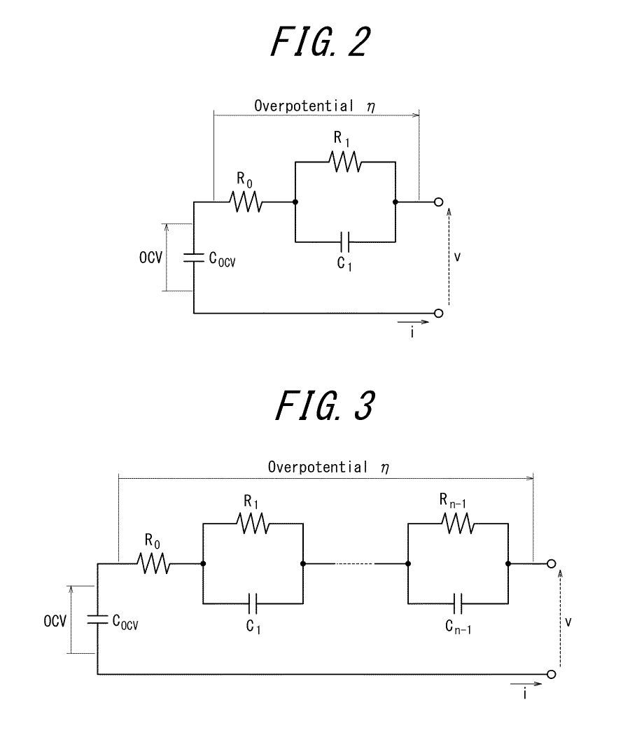

Based on the charge/discharge current signal i input from the current sensor 2 and the terminal voltage signal v input from the voltage sensor 3, the parameter estimation unit 4 uses a battery equivalent circuit (illustrated in FIG. 2) set in the battery equivalent circuit model 4A to identify parameters of a transfer function of the battery equivalent circuit, as described below.

As illustrated in FIG. 2, the battery equivalent circuit model 4A includes two components: OCV and overpotential η.

The overpotential portion represents a voltage drop due to internal resistance in the battery 1 and is configured with a resistor R₀ for electrolyte resistance or the like, connected in series to a parallel circuit of a resistor R₁ and capacitor C₁ that simulate the electrode internal ion diffusion process.

On the other hand, the OCV portion is represented by the voltage across a capacitor C_{OCV} and is connected in series to the resistor R₀ of the overpotential portion.

Accordingly, the terminal voltage value v is the sum of the OCV value and the η value.

The open circuit voltage estimation unit 5 determines the battery overpotential value using the parameters identified by the parameter estimation unit 4 and the charge/discharge current value i detected by the current sensor 2 and subtracts the overpotential value from the terminal voltage value to obtain an open circuit voltage estimated value OCV_est. Details are provided below. The OCV estimated value OCV_est thus estimated is output to the state of charge calculation unit 6.

A data map, obtained in advance by experiment, of the relationship between the open circuit voltage value and the state of charge of the battery 1 is stored in the state of charge calculation unit 6, which determines the SOC corresponding to the OCV_est value input from the open circuit voltage estimation unit 5 and outputs the result as the SOC of the battery 1.

The method, performed in the parameter estimation unit 4, for identifying parameters of the battery equivalent circuit is described below.

As this method for identification, an algorithm called Simplified Refined Instrumental Variable for Continuous-time systems (SRIVC method), which is one type of method for continuous-time system identification, is used in the present embodiment.

Therefore, this algorithm is first described. Note that in the equations below, the subscript _est indicates an “estimate”, and the superscript T indicates a “transpose matrix”.

The differential equation describing the I/O relationship in the system to be identified is considered to be equation (1) below.

Y⁽ⁿ⁾(t)+a₁Y⁽ⁿ⁻¹⁾(t)+ . . . +aₙy(t)=b₀u^{(m)}(t)+b₁u^{(m-1)}(t)+ . . . +bₘu(t) (1)

In this equation, y(t) is an output variable, u(t) is an input variable, and a₁ to aₙ and b₁ to bₙ, are coefficients (parameters).

The superscript in y⁽ⁿ⁾(t) indicates an n-order time derivative, and the superscript in u^{(m)}(t) indicates an m-order time derivative. Calculation of a high-order derivative is difficult, and therefore a Laplace transform of equation (1) above yields equation (2) below.

(sⁿ+a₁sⁿ⁻¹+ . . . +aₙ)Y(s)=(b₀s^{m}+b₁s^{m-1}+ . . . +bₘ)U(s)+(c₁sⁿ⁻¹+c₂sⁿ⁻²+ . . . +cₙ) (2)

In this equation, Y(s) and U(s) are Laplace transforms of y(t) and u(t), and c₁ to cₙ are constants related to the initial value.

An algorithm for estimating a₁ to aₙ, b₁ to bₘ, and c₁ to cₙ is now considered.

A(s):=sⁿ+a₁sⁿ⁻¹+ . . . +aₙ (3)

With this definition, dividing both sides of equation (2) by this estimated value A_est(s) yields equation (4) below.

$$( {s}^{n} + {a}_{1} {s}^{n - 1} + … + {a}_{n} ) \frac{Y ( s )}{A\_est ( s )} = + ( {b}_{0} {s}^{m} + {b}_{1} {s}^{m - 1} + … + {b}_{m} ) \frac{U ( s )}{A\_est ( s )} + ( {c}_{1} {s}^{n - 1} + {c}_{2} {s}^{n - 2} + … + {c}_{n} ) \frac{1}{A\_est ( s )} \qquad ( 4 )$$

An inverse Laplace transform of equation (4) yields equation (5) below:

y_{f}⁽ⁿ⁾(t)+a₁y_{f}⁽ⁿ⁻¹⁾(t)++aₙy_{f}(t)=b₀u_{f}^{(m)}(t)+b₁u_{f}^{(m-1)}(t)+ . . . +bₘu_{f}(t)+c₁δ_{f}⁽ⁿ⁻¹⁾(t)+c₂δ_{f}⁽ⁿ⁻²⁾(t)+ . . . +cₙδ_{f}(t) (5)

where y_{f}(t), u_{f}(t), and δ_{f}(t) are respectively defined in equations (6) through (8) below.

$$\begin{matrix}{y}_{f} ( t ) = {L}^{- 1} [ \frac{Y ( s )}{A\_est ( s )} ] = \frac{1}{A\_est ( p )} y ( t ) & ( 6 ) \\ {u}_{f} ( t ) = {L}^{- 1} [ \frac{U ( s )}{A\_est ( s )} ] = \frac{1}{A\_est ( p )} u ( t ) & ( 7 ) \\ {δ}_{f} ( t ) = {L}^{- 1} [ \frac{Y ( s )}{A\_est ( s )} ] = \frac{1}{A\_est ( p )} δ ( t ) & ( 8 )\end{matrix}$$

Note that p is a differential operator, and δ(t) is a unit impulse signal.

A parameter vector θ, a regression vector ψ_{f}(tₖ), an output vector y_{f}(tₖ), an input vector u_{f}(tₖ), and a unit impulse vector δ_{f}(tₖ) are defined in equations (9) to (13) below.

θ=[a₁ . . . aₙb₀ . . . bₘc₁ . . . cₙ]^{T} (9)

ψ_{f}(tₖ)=[−y_{f}^{T}(tₖ)u_{f}^{T}(tₖ)δ_{f}^{T}(tₖ)]^{T} (10)

y_{f}(tₖ)=[y_{f}⁽ⁿ⁻¹⁾(tₖ)y_{f}⁽ⁿ⁻²⁾(tₖ) . . . y_{f}(tₖ)]^{T} (11)

u_{f}(tₖ)=[u_{f}^{(m)}(tₖ)u_{f}^{(m-1)}(tₖ) . . . u_{f}(tₖ)]^{T} (12)

δ_{f}(tₖ)=[δ_{f}⁽ⁿ⁻¹⁾(tₖ)δ_{f}⁽ⁿ⁻²⁾(tₖ) . . . δ_{f}(tₖ)]^{T} (13)

Equation (14) below is thus obtained.

y_{f}⁽ⁿ⁾(tₖ)=ψ_{f}^{T}(tₖ)θ (14)

In this equation, tₖ is the time corresponding to the k^{th} sampling.

Next, an instrumental variable x(t) is calculated in equation (15).

$$x ( t ) = \frac{B\_est ( p )}{A\_est ( p )} u ( t ) + \frac{C\_est ( p )}{A\_est ( p )} δ ( t ) \qquad ( 15 )$$

B_est(p) and C_est(p) in this equation are estimated values from equations (16) and (17).

B(S):=(b₀s^{m}+b₁s^{m-1}+ . . . +bₘ) (16)

C(S):=(c₁sⁿ⁻¹+c₂sⁿ⁻²+ . . . +cₙ) (17)

This instrumental variable is filtered as in equation (18) below, and an instrumental variable vector ζ_{f}(tₖ) is generated as shown in equation (19).

$$\begin{matrix}{x}_{f} ( t ) = \frac{1}{A\_est ( p )} x ( t ) & ( 18 ) \\ {ζ}_{f} ( {t}_{k} ) = {[ - {x}_{f}^{T} ( {t}_{k} ) {u}_{f}^{T} ( {t}_{k} ) {δ}_{f}^{T} ( {t}_{k} ) ]}^{T} & ( 19 )\end{matrix}$$

Then, a parameter vector θ_est is calculated as in equation (20) below:

$$θ\_est = {[ {\sum }_{k = 1}^{N} {ζ}_{f} ( {t}_{k} ) {ψ}_{f}^{( n )} ( {t}_{k} ) ]}^{- 1} {\sum }_{k = 1}^{N} {ζ}_{f} ( {t}_{k} ) {y}_{f}^{( n )} ( {t}_{k} ) \qquad ( 20 )$$

where x_{f}(tₖ) is as in equation (21) below.

x_{f}(tₖ)=[x_{f}⁽ⁿ⁻¹⁾(tₖ)x_{f}⁽ⁿ⁻²⁾(tₖ) . . . x_{f}(tₖ)]^{T} (21)

In light of the above, the SRIVC algorithm can be summarized as follows.

First, in step 1, an appropriate filter 1/A_est(s) is used to filter I/O data. From the resulting regression vector ψ_{f}(tₖ) and output vector y_{f}⁽ⁿ⁾(tₖ), the method of least squares equation (22), i.e.

$$θ\_est = {[ {\sum }_{k = 1}^{N} {ψ}_{f} ( {t}_{k} ) {ψ}_{f}^{T} ( {t}_{k} ) ]}^{- 1} {\sum }_{k = 1}^{N} {ψ}_{f} ( {t}_{k} ) {y}_{f}^{( n )} ( {t}_{k} ) \qquad ( 22 )$$

is used to calculate the estimated value θ_est of the parameter θ. This is set as the first iteration.

Next, in step 2, the following three steps S21, S22, and S23 are repeated from j=2 until convergence.

Step S21: from the parameter θ^{j-1} obtained in the (j−1)^{th} iteration, A_est(s), B_est(s), and C_est(s) are created, and the instrumental variable x(t) is calculated.

Step S22: y, u, and x are filtered with 1/A_est(s) to calculate y_{f}⁽ⁿ⁾(tₖ), the regression vector ψ_{f}(tₖ), and the instrumental variable vector ζ_{f}(tₖ).

Step S23: using the calculated values, parameters are estimated with equation (23) below.

$${θ\_est}^{j} = {[ {\sum }_{k = 1}^{N} {ζ}_{f} ( {t}_{k} ) {ψ}_{f}^{T} ( {t}_{k} ) ]}^{- 1} {\sum }_{k = 1}^{N} {ζ}_{f} ( {t}_{k} ) {y}_{f}^{( n )} ( {t}_{k} ) \qquad ( 23 )$$

Next, a method for determining the initial values in equation (2) is described below.

The initial values c₁ to cₙ correspond to the initial values of the state variables in observable canonical form.

In other words, where x is a state vector, u is an input vector, y is an output vector, A_est is a system estimated value matrix, b_est is an input matrix, c_est is an output matrix, and d is a transfer matrix, the equation of state and the output equation of a linear system are respectively represented by equations (24-1) and (24-2) below.

\dot{x}=A_estx+b_estu (24-1)

y=c_est^{T}x+du (24-2)

When the corresponding transfer function is as in equation (25) below, i.e.

$$\frac{{b}_{1}^{′} {s}^{n - 1} + … + {b}_{n}^{′}}{{s}^{n} + {a}_{1} {s}^{n - 1} + … + {a}_{n}} \qquad ( 25 )$$

then equations (26) to (28),

$$\begin{matrix}{A}_{\_ e st} = [ \begin{matrix}0 & … & … & … & 0 & - {a}_{n} \\ 1 & 0 & … & … & 0 & - {a}_{n - 1} \\ 0 & 1 & ⋱ & & ⋮ & ⋮ \\ ⋮ & ⋮ & ⋱ & ⋱ & ⋮ & ⋮ \\ ⋮ & ⋮ & & ⋱ & 0 & ⋮ \\ 0 & 0 & … & 0 & 1 & - {a}_{1}\end{matrix} ] & ( 26 ) \\ {b}_{est} = [ \begin{matrix}{b}_{n}^{′} & {b}_{n - 1}^{′} & … & {{b}_{1}^{′} ]}^{T}\end{matrix} & ( 27 ) \\ {c}_{\_est} = [ \begin{matrix}0 & … & {1 ]}^{T}\end{matrix} & ( 28 )\end{matrix}$$

yield equation (29) below.

x(0)=[cₙcₙ₋₁ . . . c₁]^{T} (29)

On the other hand, as illustrated in FIG. 3, when the equivalent circuit model of the battery 1 is a circuit in which n−1 parallel circuits of resistors Rₙ, (m=1 to n−1) and capacitors Cm (m=1 to n−1) are connected in series, the voltage of the capacitor C_{OCV} is z_{OCV}, and the voltage of Cm is zₘ, then letting these be state variables, the equations of state are as in equations (30) to (36) below.

$$\begin{matrix}\dot{z} = Az + bu & ( 30 ) \\ y = {c}^{T} z + du & ( 31 ) \\ A = [ \begin{matrix}0 & … & … & … & 0 \\ ⋮ & - \frac{1}{{C}_{1} {R}_{1}} & … & … & 0 \\ ⋮ & 0 & ⋱ & & ⋮ \\ ⋮ & ⋮ & & ⋱ & 0 \\ 0 & 0 & … & 0 & - \frac{1}{{C}_{n - 1} {R}_{n - 1}}\end{matrix} ] & ( 32 ) \\ b = {[ \begin{matrix}\frac{1}{{C}_{OCV}} & \frac{1}{{C}_{1}} & … & \frac{1}{{C}_{n - 1}}\end{matrix} ]}^{T} & ( 33 ) \\ c = {[ \begin{matrix}1 & … & 1\end{matrix} ]}^{T} & ( 34 ) \\ d = {R}_{0} & ( 35 ) \\ z = {[ \begin{matrix}{z}_{OCV} & {z}_{1} & … & {z}_{n - 1}\end{matrix} ]}^{T} & ( 36 )\end{matrix}$$

Here, the transform x=Tz is considered, where T is a non-singular matrix.

Equations (37) to (39) below thus hold.

A=T^{-T}A_estT (37)

b=T^{-T}b_est (38)

c^{T}=C_est^{T}T (39)

Focusing on the forms of A_est and c_est and solving for T to satisfy these equations yield equation (40) below.

$$T = [ \begin{matrix}{a}_{n - 1} & {a}_{n - 2} & {a}_{n - 3} & … & {a}_{1} & 1 \\ {a}_{n - 2} & {a}_{n - 3} & … & {a}_{1} & 1 & 0 \\ {a}_{n - 3} & … & {a}_{1} & 1 & 0 & ⋮ \\ ⋮ & … & 1 & 0 & … & ⋮ \\ {a}_{1} & 1 & 0 & … & … & ⋮ \\ 1 & 0 & … & … & … & 0\end{matrix} ] [ \begin{matrix}{c}^{T} \\ {c}^{T} A \\ {c}^{T} {A}^{2} \\ ⋮ \\ ⋮ \\ {c}^{T} {A}^{n - 1}\end{matrix} ] \qquad ( 40 )$$

Using this T to calculate equation (41) below, i.e.

$$z ( 0 ) = {T}^{- 1} [ \begin{matrix}{C}_{n} \\ {C}_{n - 1} \\ ⋮ \\ {C}_{1}\end{matrix} ] \qquad ( 41 )$$

allows for determination of the initial value of voltage for each capacitor in the equivalent circuit.

When calculating the overpotential η in the estimation of OCV in the open circuit voltage estimation unit 5, this initial value of voltage is used.

Using the above SRIVC method, in the parameter estimation unit 4 illustrated in FIG. 1, the parameters for the battery equivalent circuit illustrated in FIG. 2 are estimated in the following way.

Specifically, where the current i flowing in the equivalent circuit illustrated in FIG. 2 is an input u and the terminal voltage v is an output y, seeking the transfer function between these yields equations (42) to (46) below.

$$\begin{matrix}G ( s ) = \frac{{b}_{0} {s}^{2} + {b}_{1} s + {b}_{2}}{{s}^{2} + {a}_{1} s} & ( 42 ) \\ {a}_{1} = \frac{1}{{C}_{1} {R}_{1}} & ( 43 ) \\ {b}_{0} = {R}_{0} & ( 44 ) \\ {b}_{1} = \frac{1}{{C}_{OCV}} + \frac{1}{{C}_{1}} + \frac{{R}_{0}}{{C}_{1} {R}_{1}} & ( 45 ) \\ {b}_{2} = \frac{1}{{C}_{OCV} {C}_{1} {R}_{1}} & ( 46 )\end{matrix}$$

In order to apply the SRIVC method to these, equations (47) to (54) below may be adopted, taking the existence of an integrator into consideration.

A(s):=s²+a₁s (47)

B(s):=b₀s²+b₁s+b₂ (48)

C(s):=c₁s+c₂ (49)

θ=[a₁b₀b₁b₂c₁c₂]^{T} (50)

ψ_{f}(tₖ)=[−y_{f}⁽¹⁾(tₖ)u_{f}^{T}(tₖ)δ_{f}^{T}(tₖ)]^{T} (51)

ζ_{f}(tₖ)=[−y_{f}⁽¹⁾(tₖ)u_{f}^{T}(tₖ)δ_{f}^{T}(tₖ)]^{T} (52)

u_{f}(tₖ)=[u_{f}⁽²⁾(tₖ)u_{f}⁽¹⁾(tₖ)u_{f}(tₖ)]^{T} (53)

δ_{f}(tₖ)=[δ_{f}⁽¹⁾(tₖ)δ_{f}(tₖ)]^{T} (54)

The parameters of the equivalent circuit can be sought as in equations (55) to (58) below from the parameters a₁, b₀, b₁, and b₂ of the transfer function estimated in this way.

$$\begin{matrix}{R}_{0} = {b}_{0} & ( 55 ) \\ {R}_{1} = - \frac{{a}_{1}^{2} {b}_{0} - {a}_{1} {b}_{1} + {b}_{2}}{{a}_{1}^{2}} & ( 56 ) \\ {C}_{OCV} = \frac{{a}_{1}}{{b}_{2}} & ( 57 ) \\ {C}_{1} = \frac{{a}_{1}}{{a}_{1}^{2} {b}_{0} - {a}_{1} {b}_{1} + {b}_{2}} & ( 58 )\end{matrix}$$

On the other hand, in the open circuit voltage estimation unit 5, the parameters of the equivalent circuit obtained by the parameter estimation unit 4 are used, and the transfer function to the overpotential η becomes as in equation (59) below.

$${G}_{η} ( s ) = {R}_{0} + \frac{{R}_{1}}{1 + {sC}_{1} {R}_{1}} \qquad ( 59 )$$

Since the input current u=i, the estimated value of the overpotential is given by equation (60) below.

η_est(s)=G_{η}(s)u(t) (60)

Accordingly, the open circuit voltage estimated value OCV_est is yielded by equation (61) below.

OCV_est(t)=Y(t)−η_est (61)

Next, operations of the apparatus for state of charge estimation for the battery 1 are described.

Upon vehicle power being turned on, the current sensor 2 outputs a charge/discharge current signal i corresponding to the magnitude of the current in the battery 1 to the parameter estimation unit 4. The voltage sensor 3 also outputs a terminal voltage signal v corresponding to the magnitude of the terminal voltage of the battery 1 to the parameter estimation unit 4.

Using the charge/discharge current signal i and the terminal voltage signal v, the parameter estimation unit 4 identifies the parameters of the battery equivalent circuit, illustrated in FIG. 3, of the battery equivalent circuit model 4A.

On vehicle startup, and periodically thereafter, this parameter identification is performed using the SRIVC method, which is a method for continuous-time system identification as described above. In this case, the SRIVC method is used to identify parameters of an equation that is a Laplace transform, taking initial values into consideration, of the differential equation expressing the target system. Accordingly, in addition to the resistors R₀ and R₁, C₁, and the like, the initial values c₁ to c₁, are also estimated.

These parameters obtained by the parameter estimation unit 4 are output to the open circuit voltage estimation unit 5.

In the open circuit voltage estimation unit 5, the parameters obtained by the parameter estimation unit 4 are fit to the battery equivalent circuit, illustrated in FIG. 2, of the battery equivalent circuit model 4A. The transfer function from the input current u=i to the overpotential η is calculated with equation (59) above, and using equation (60), an estimated value η_est(t) of the overpotential is calculated. With equation (61), the overpotential is subtracted from the terminal voltage to yield the open circuit voltage estimated value OCV_est. This value is output to the state of charge calculation unit 6.

The state of charge calculation unit 6 uses the data map, stored in advance, representing the relationship between the open circuit voltage value and the state of charge to determine the state of charge corresponding to the open circuit voltage estimated value OCV_est input from the open circuit voltage estimation unit 5 and outputs the result.

This state of charge is used, for example, to infer the drivable distance of the vehicle.

Next, the results are described for a numerical simulation when performing continuous-time identification using the above SRVIC method in an apparatus for state of charge estimation including the apparatus for parameter estimation of the present embodiment.

In the simulation, the input current estimated during driving of an actual electric vehicle was input into the detailed battery equivalent circuit model in FIG. 3, constructed in a computer, to obtain output voltage.

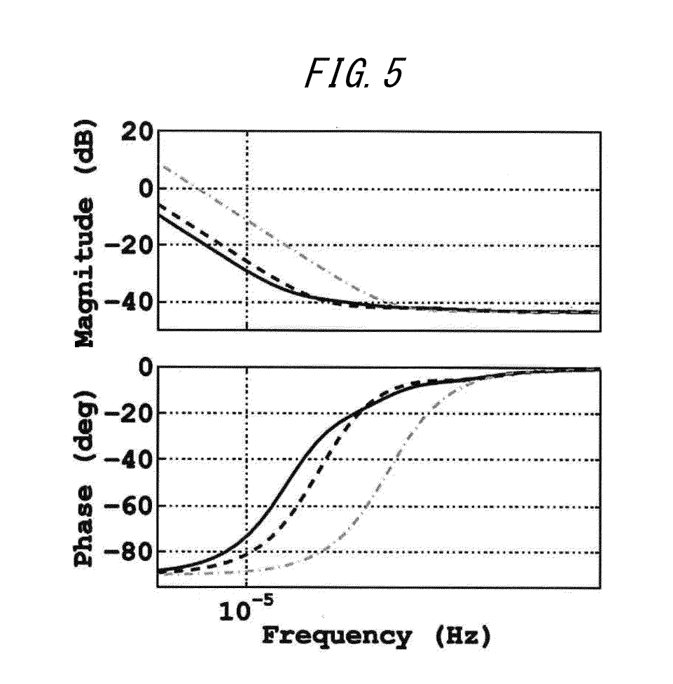

In FIGS. 5 to 8 below, the solid line indicates the true system, the dashed line indicates estimated values by continuous-time system identification, and the gray alternate long and short dash line indicates estimated values by discrete-time system identification.

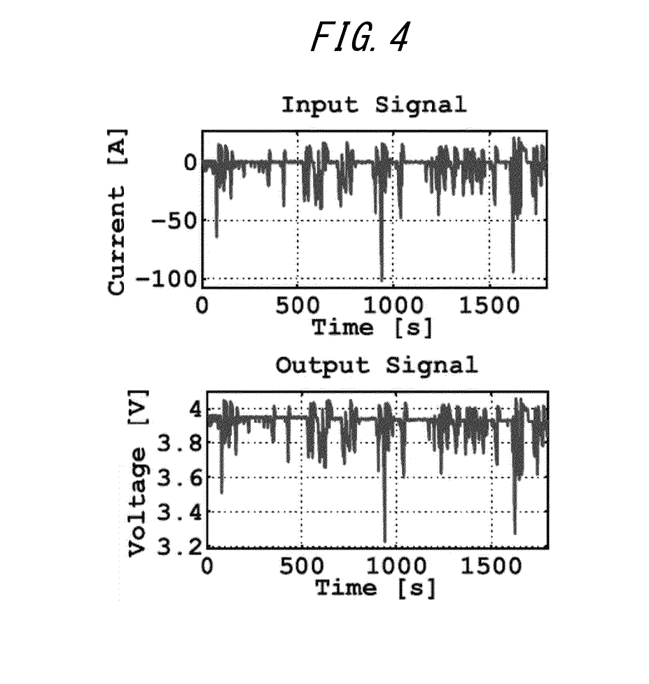

FIG. 4 shows the I/O data. The upper half of FIG. 4 shows the input signal, with time [s] on the horizontal axis and the magnitude of current [A] on the vertical axis, and the lower half of FIG. 4 shows time [s] on the horizontal axis and the magnitude of terminal voltage [V] of the battery 1 on the vertical axis.

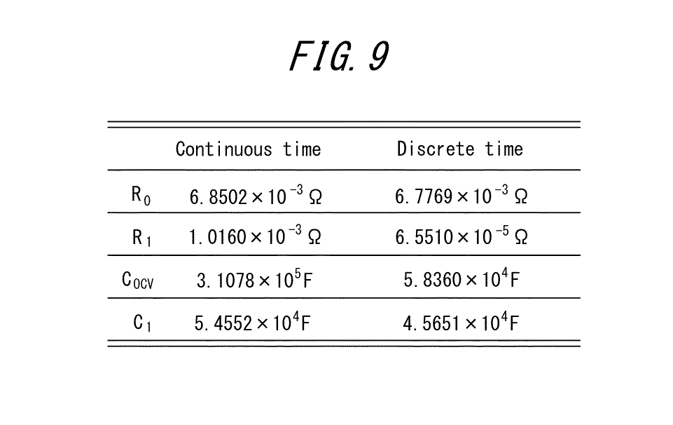

The SRIVC method, which is a method for continuous-time system identification, was applied to these data in FIG. 4 to estimate parameters of the equivalent circuit for the battery 1. For the sake of comparison, parameters were also estimated using discrete-time system identification. FIG. 9 shows the estimated equivalent circuit parameters.

FIG. 5 shows a comparison using a Bode plot. The upper half of FIG. 5 shows gain [db] (vertical axis) versus frequency [Hz] (horizontal axis), and the lower half of FIG. 5 shows phase [deg] (vertical axis) versus frequency [Hz] (horizontal axis).

As is clear from FIG. 5, the estimated values with continuous-time system identification are closer to the true system than the estimated values with discrete-time system identification.

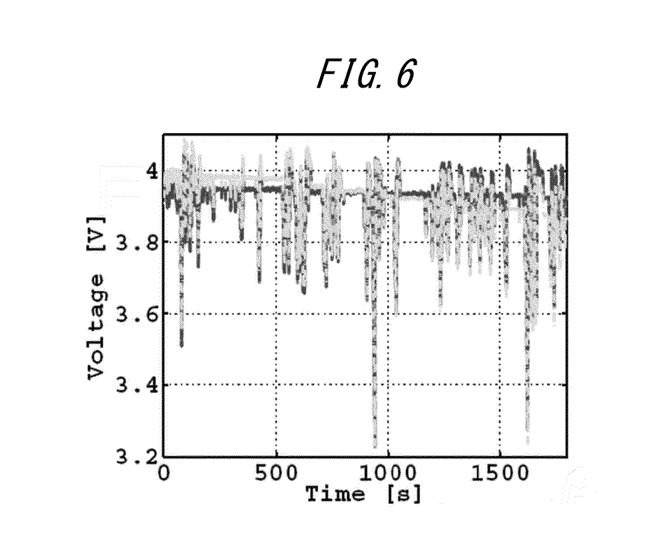

FIG. 6 shows a comparison of true output values and model output values. FIG. 6 shows the output values [V] (vertical axis) versus time [s] (horizontal axis). The true output values shown by the solid line and the estimated values by continuous-time system identification shown by the dashed line nearly overlap. Only the estimated values by discrete-time system identification shown by the gray alternate long and short dash line are misaligned.

Calculating the fit ratio from the data in FIG. 6 yields 99% for continuous-time system identification as opposed to 66% for discrete-time system identification.

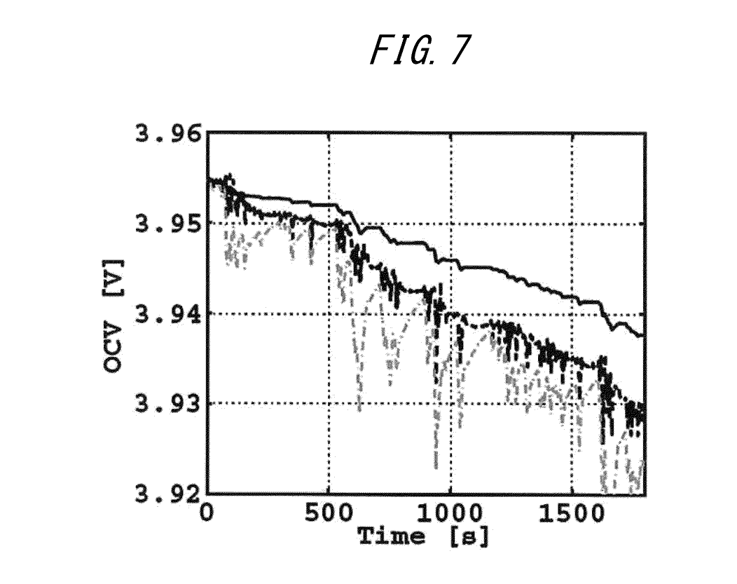

Next, FIG. 7 shows the results of estimating OCV using the above results. FIG. 7 shows the OCV [V] (vertical axis) versus time [s] (horizontal axis).

As is clear from FIG. 7, the estimated values with continuous-time system identification are closer to the true system than the estimated values with discrete-time system identification for the open circuit voltage estimated value OCV_est as well.

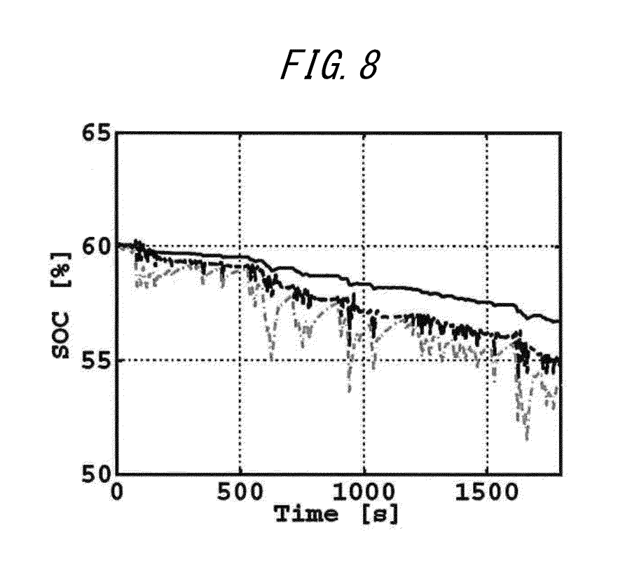

FIG. 8 shows the results of converting the open circuit voltage estimated value OCV_est obtained above into a SOC. FIG. 8 shows the SOC [%] (vertical axis) versus time [s] (horizontal axis).

As is clear from FIG. 8, the error in SOC is reduced to approximately 2% with the method using continuous-time system identification, whereas the error increases considerably with the method using discrete-time system identification.

According to the apparatus for parameter estimation of Embodiment 1 with the above structure, when performing system identification by identifying circuit parameters of an equivalent circuit model for the battery 1, the SRIVC method is used for continuous-time system identification, and the initial values of the system expressed by the transfer function thereof are estimated at the same time as the parameters.

Accordingly, the initial values can be estimated more accurately, and as a result, the open circuit voltage estimated value OCV_est and the state of charge of the battery 1 can be estimated to a higher degree of accuracy.

Therefore, time is not required to establish experiment conditions for identification of the battery equivalent circuit model.

Furthermore, even if the vehicle-mounted battery is exchanged for a different type, identification of the battery equivalent circuit can be performed accurately.

The present invention has been described based on the above embodiments, yet the present invention is not limited to these embodiments and includes any design modification or the like within the spirit and scope of the present invention.

For example, the equivalent circuit model of the battery 1 is not limited to FIGS. 2 and 3, and a different model may be used. With a Foster-type model, for example, the number of levels of parallel circuits is preferably large in the model for calculating the initial values, yet the number need not be as large in the model for calculating the overpotential. A number appropriate for the purpose should be set by taking the estimation accuracy and the difficulty of calculation into consideration.

In the present invention, a method for continuous-time system identification other than the SRIVC method may be used to identify the initial values.

After estimating the initial values with the method for continuous-time system identification of the present invention, parameters may also be estimated by discrete-time system identification.

Furthermore, the target system according to the present invention is not limited to a battery in an electric vehicle and may be any other system for which estimation of initial values is not easy.

### REFERENCE SIGNS LIST

1: Battery
2: Current sensor (input signal detection unit)
3: Voltage sensor (output signal detection unit)
4: Parameter estimation unit (parameter identification unit)
4A: Battery equivalent circuit model (mathematical model)
5: Open circuit voltage estimation unit
6: State of charge calculation unit

1. An apparatus for parameter estimation, the apparatus comprising:
a mathematical model expressing a target system as a differential equation;
an input signal detection unit configured to detect an input signal to the target system;
an output signal detection unit configured to detect an output signal from the target system; and
a parameter identification unit configured to perform system identification by taking the input signal and the output signal as input and using the input signal and the output signal to identify a parameter used in a transfer function of the mathematical model, wherein
the parameter identification unit performs, simultaneously with the system identification, continuous-time system identification of an initial value of the transfer function based on the input signal and the output signal.

2. The apparatus according to claim 1, wherein
the parameter identification unit applies an SRIVC method to the continuous-time system identification.

3. The apparatus according to claim 1 or 2, wherein
the target system is a secondary battery,
the input signal is a charge/discharge current of the secondary battery, and
the output signal is a terminal voltage of the secondary battery.
